(19) United States
(12) Patent Application Publication
(10) Pub. No.: US 2007/0099410 A1
(43) Pub. Date: May 3, 2007

(54) Hard intermetallic bonding of wafers for MEMS applications

(76) Inventors: William D. Sawyer, Arlington, MA (US); Jonathan J. Bernstein, Medfield, MA (US)

Correspondence Address: MCDERMOTT WILL & EMERY LLP, 28 STATE STREET, BOSTON, MA, 02109-1775, US

(21) Appl. No.: 11/262,863

(22) Filed: Oct. 31, 2005

(51) Int. Cl. H01L 21/44; H01L 21/4763

(52) U.S. Cl. 438/612; 438/642; 257/E23.023

(57) ABSTRACT

A method of bonding two substrates in MEMS applications includes depositing a first metal in a bonding area on a first substrate, depositing a second metal, which is different from the first metal, in a bonding area on a second substrate, place the first substrate and the second substrate together such that the deposited first metal on the first substrate is aligned and in contact with the deposited second metal on the second substrate, and annealing the first metal and second metal to form an intermetallic bond between the first substrate and the second substrate.

### FIELD OF THE INVENTION

The present invention relates generally to methods of bonding wafers for MEMS applications, and more particularly, relates to hard intermetallic bonding of wafers for MEMS applications and also relates to MEMS devices having an intermetallic bond.

### BACKGROUND OF THE INVENTION

The fabrication of MEMS devices often requires bonding one wafer or substrate to another wafer or substrate. One type of conventional method for bonding a silicon wafer to another silicon wafer is known as silicon direct bonding (SDB) or fusion bonding.

FIG. 1 illustrates a cross-section of a MEMS device having two substrates bonded by silicon direct bonding. The process of silicon direct bonding generally includes several steps. The first step of silicon direct bonding is to produce silicon wafers which have a very smooth and flat surface. Total thickness variation (TTV) is often used to describe the flatness of a wafer. For a 0.4 mm thick wafer to be bonded using silicon direct bonding technique, a TTV specification of 3 μm or less is typically required.

The second step of silicon direct bonding is to prepare the surface of the silicon wafers which are to be bonded. Organic contaminants, metals and especially particles must be removed from the surfaces of the silicon wafers. In addition, the chemical state of the surfaces is modified to enhance the strength of the bond to be formed between the two surfaces. There are several methods for modifying the chemical states of the surface, including roughening or activation of the surfaces using plasmas of O₂, Ar, or other gases, followed by (or preceded by) wet chemical treatments.

The third step of the silicon direct bonding is to contact the wafers. The interface between the bonded and unbonded region is called the “bond front”, which proceeds across the surfaces to be bonded when wafer contact is initiated. An operator must avoid trapping gas between the bonded surfaces, e.g., by initiating the bonding on one side of the wafer first.

The final step in the silicon direct bonding is an anneal process. The anneal process increases the strength of the silicon direct bond.

The silicon direct bond is traditionally used as a rigid, mechanical bond for MEMS applications. The strength of the bond is suitable for the mechanical stability of MEMS devices, allowing high mechanical Q (

$$( Q = \frac{\sqrt{M k}}{R} ,$$

where M (kg) is the mass of the resonator, k (N/m) is the spring constant, and R(N·s/m) is the resistance to motion) to be achieved. However, the interface between the bonded silicon areas usually contains SiO₂. The intermediary SiO₂ layer between the silicon surfaces may contain electron and hole traps. These electron and hole traps create a high electrical resistance across the Si—Si bond interface, which impedes electrical current from passing through silicon direct bond regions in the device. Former techniques for reducing the interfacial resistance include heavily doping both silicon layers to be bonded to reduce the depletion region at the interface. However, the dopant concentration level of the silicon layers required by the functionality of the device may place a restriction on the allowable doping level for forming an ohmic contact between the bonded surfaces.

Another technique to avoid the formation of the intermediary SiO₂ layer is to perform the surface preparation and wafer bonding steps in a high vacuum (e.g., 1×10⁻⁸ Torr) environment. The equipment required to perform surface preparation and wafer bonding in a high vacuum environment is very expensive.

Another conventional method for bonding wafers together uses soft metals as an intermediary layer between the two wafers. For example, thermal-compression bonding using metal is well known. Usually, a relatively soft and compliant metal such as copper or gold is used as the intermediary layer to establish a mechanical bond between the wafers. However, soft metals are known to creep, which causes hysteresis effects over temperature in MEMS devices. In addition, most of the soft metals do not form a low resistance ohmic contact with a silicon substrate.

United States Patent Application Publication No. 2004/0149373 to Weihs et al. discloses a method of bonding two bodies using an assembly including a freestanding multilayer reactive foil sandwiched between two joining materials. The assembly is placed between the two bodies to be joined. The multilayer reactive foil includes two chemically distinct materials. An external stimulus (e.g., spark) initiates chemical reactions between the two materials of the multilayer reactive foil, that generates heat to melt the joining materials to join the bodies that are pressed against the joining materials. The method in Weihs et al. usually uses a relatively soft and compliant metal such as silver as the joining material. Similar to the above-described thermal-compression bonding technique, devices formed by this method may also suffer from creep and hysteresis.

Accordingly, there is a need for a new method for bonding substrates, such that the bond between the substrates presents a high mechanical stability and high electrical conductivity.

### SUMMARY OF THE INVENTION

The present invention provides methods for bonding wafers or substrates (hereinafter referred to as substrates) in semiconductor device fabrication. The methods disclosed herein apply to semiconductor fabrications in both wafer level and individual device level. According to one aspect of the present invention, a metal is used as an intermediary bonding material to bond a silicon substrate with another substrate, which may be made from silicon, silicon carbide, glass (e.g., HOYA SD-2™ manufactured by HOYA Corporation), ceramic (AlN, Al₂O₃, etc.), fused silicon dioxide, PYREX™, etc. Most transition metals, which are known to be able to form a silicide with silicon if annealed, can be used as the intermediary bonding material. Exemplary metals include but are not limited to Pt, Pd, Co, Mo, Ta, Cr, Ti, W, Al, Nb, and Sn.

According to one preferred embodiment of the present invention, the two substrates to be bonded are first prepared. A thin layer of the bond metal (e.g., Pt) is deposited by sputtering, evaporation, or other thin film deposition techniques on the bonding areas on one of the substrates. If one substrate is made from silicon and the other substrate is not made from silicon, the bond metal is deposited on the substrate which is not made from silicon. The deposited metal layer is patterned through photolithography or shadow masks. The two substrates are then aligned and the areas that are to be bonded are brought into contact. The two substrates with the intermediary metal layer are then annealed to cause the metal atoms to diffuse into the silicon substrate and silicon atoms to diffuse into the metal. The inter-diffusion of metal and silicon atoms at the bond interface forms a rigid mechanical bond. At the same time a metal silicide is formed which establishes an ohmic contact between the two substrates at the bonding areas.

According to another preferred embodiment of the present invention, two metals are used to bond two substrates together. A first metal is deposited by sputtering, evaporation, or other thin film deposition techniques on bonding areas to form metal contacts on the first substrate. A second metal, which is different from the first metal, is deposited on bonding areas to form metal contacts on the second substrate. The metal contacts on both substrates preferably have a uniform outer surface. The first and second metals are preferably selected from but not limited to a group consisting of Pt, Pd, Co, Mo, Ta, Cr, Ti, W, Al, Nb, and Sn. The two substrates are then aligned and the deposited metal contacts on the two substrates are brought into contact with each other. Preferably, the two substrates are pressed against each other, such that the deposited metal contacts are in intimate contact. The two metal contacts are then annealed at a preferable temperature (preferably below the melting point of the metal contacts) that allows the two metals to diffuse into each other, thereby forming an intermetallic bond between the two substrates. The intermetallic bond includes intermetallic compound formed by the atoms of the two metals. An example of such an intermetallic compound which can be used for bonding is Ni₃Al, in which the two metals respectively are Ni and Al. Other metal pairs include but are not limited to Ti—Al, Ti—Cr, Al—Nb, Pd—Al, Pt—Al, and Ti—Sn.

In a further preferred embodiment of the present invention, the contacts on the two substrates include a multi-layer stack of alternating thin layers of at least two materials (preferably two metals), which are deposited on the bonding areas of the substrates. For example, each contact may include alternating layers of Ni and Al, or Pd and Al, or Ti and Sn, or Ni and Si. The arrangement expedites the inter-diffusion of the bonding materials and intermetallic (or silicide) reactions between the two materials.

The methods of silicide bonding and intermetallic bonding described in this disclosure form a rigid mechanical bond between two substrates. It also creates a low resistance ohmic contact between the two substrates. The combination of a strong mechanical bond and the conduction of current across the interface of two substrates provide MEMS device engineers more options and better manufacturability in device design. The bonding temperature is also much lower than for silicon direct bonding, hence devices with metal layers can be safely processed.

### BRIEF DESCRIPTION OF THE DRAWINGS

FIG. 1 is a schematic cross-sectional view of a MEMS device having two substrates bonded by a conventional silicon direct bonding technique;

FIG. 2 is a schematic cross-sectional view of a MEMS device having two substrates aligned before bonding according to one preferred embodiment of the present invention;

FIG. 3 is a schematic cross-sectional view of the MEMS of FIG. 2, showing that the two substrates are bonded together according to one preferred embodiment of the present invention;

FIG. 4 is a schematic cross-sectional view of a MEMS device having two substrates aligned before bonding according to another preferred embodiment of the present invention;

FIG. 5 is a schematic cross-sectional view of the MEMS of FIG. 4, showing that the two substrates are bonded together according to one preferred embodiment of the present invention;

FIG. 6 is a schematic cross-sectional view of a MEMS device having two substrates aligned before bonding according to a further preferred embodiment of the present invention; and

FIG. 7 shows a graph of micro-hardness vs. melting temperature for metals and intermetallic compounds.

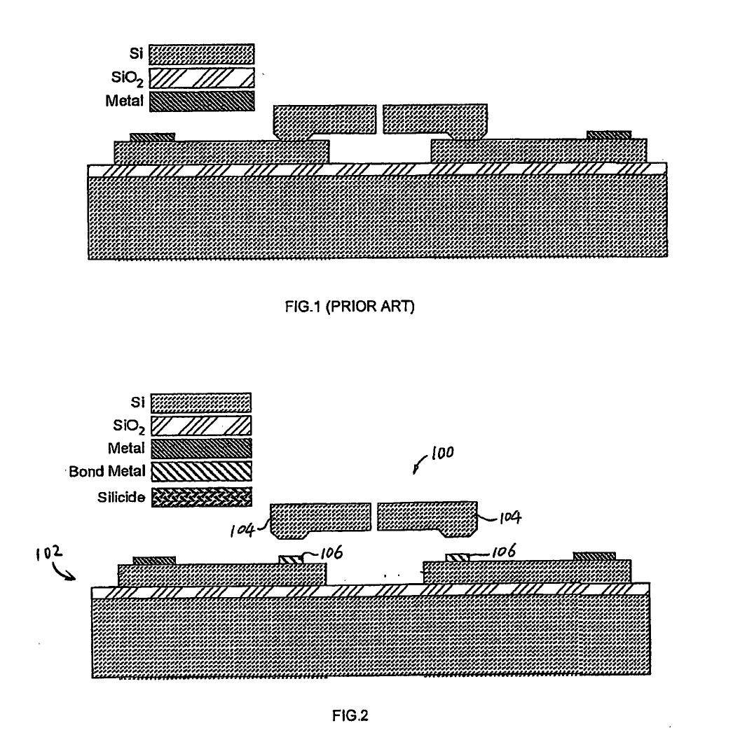

### DETAILED DESCRIPTION OF THE PREFERRED EMBODIMENTS

The present invention provides methods for bonding substrates in semiconductor device fabrication, such that the bond between the substrates exhibits a high mechanical stability and electrical conductivity. The present invention also provides MEMS devices having substrates bonded with an intermediary layer, such that the bonding area has a high mechanical stability and electrical conductivity.

According to one aspect of the present invention, a metal is used as an intermediary bonding material to bond a silicon substrate with another substrate, which may be made from silicon, silicon carbide, glass (e.g., HOYA SD-2™), ceramic (AlN, Al₂O₃, etc.), fused silicon dioxide, PYREX™, etc. Most transition metals, which are known to be able to form a silicide with silicon if annealed; can be used as the intermediary bonding material. Exemplary metals include but not limited to Pt, Pd, Co, Mo, Ta, Cr, Ti, W, Al, Nb, Sn, Zr, Ni, V, and Mo.

FIGS. 2 and 3 illustrate one preferred embodiment according to the present invention. The MEMS device 100 includes a first substrate 102 and a second substrate 104. FIG. 2 shows the MEMS device before the two substrates are bonded together and FIG. 3 shows the MEMS device after the two substrates are bonded together.

The substrates to be bonded are first prepared. The process for preparation of the substrates is similar to the substrate preparation process of silicon direct bonding. The substrates with a very smooth and flat surface (a low TTV) are first produced. This is necessary so that the areas to be bonded can come into intimate contact. The bonding areas on the substrates are delineated and cleaned. Organic contaminants and particles are removed from the surfaces of the substrates. The chemical state of the surfaces is modified to enhance the strength of the bond. The methods for modifying the chemical states of the surfaces includes roughening or activation of the surfaces using plasmas of O₂, Ar, or other gases, followed by (or preceded by) wet chemical treatments.

A thin layer of the bond metal (e.g., Pt) 106 is then deposited by sputtering, evaporation, or other thin film deposition techniques on the bonding areas on one of the substrates, for example, the substrate 102. If one substrate is made from silicon and the other substrate is not made from silicon, the bond metal is deposited on the substrate which is not made from silicon. Preferably, the surface of the deposited metal 106 is uniform so that all of the areas across the surface of the bonding area of the silicon substrate 104 can come into contact with the corresponding areas of the deposited metal 106.

The two substrates 102 and 104 are then aligned and pressed together, and the areas that are to be bonded come into contact. The two substrates 102 and 104 with the intermediary metal 106 are then annealed to cause the metal atoms to diffuse into the silicon substrate and silicon atoms to diffuse into the metal. The annealing temperature is preferably below the melting point of the metal. The inter-diffusion of metal and silicon atoms at the bond interface forms a rigid mechanical bond. At the same time a metal silicide is formed which establishes an ohmic contact between the two substrates 102 and 104 at the bonding areas. The resulting bonded structure is shown in FIG. 3. In one preferred embodiment, the metal silicide bond between the two substrates is characterized by a yield strength of over 50 megapascals. In another preferred embodiment, the metal silicide bond is characterized by a yield strength of over 100 megapascals. According to a further preferred embodiment of the present invention, the metal silicide bond is characterized by a yield strength of over one gigapascal.

Many of the silicides have very high yield strength and can therefore be used in sensors requiring the utmost precision and stability.

In one exemplary embodiment, Pt is used as the intermediary bonding material between the two substrates (at least one of which is a silicon substrate). A Pt layer is first deposited on a substrate which can be made from silicon, silicon carbide, glass (e.g., HOYA SD-2™), ceramic, fused silicon dioxide, PYREX™, etc. The substrate with the deposited Pt layer is then aligned and pressed against a silicon substrate having the Pt layer facing the bonding area of the silicon substrate. The two substrates are then annealed. The silicide reaction occurs in two temperature regimes during the anneal process. When annealed at about 261° C., Pt atoms diffuse into the silicon substrate. When followed by an anneal process at about 335° C., silicon atoms diffuse into the Pt. This intermixing of the Si and Pt atoms as the Pt silicide forms creates a rigid mechanical bond. It also creates a very low Schottky barrier at the bonding areas of the two substrates for the flow of holes. At normal device operation temperatures, holes can tunnel across the Schottky barrier. As a result, the intermediary Pt silicide functions as an ohmic contact sandwiched between the two substrates. The Pt bonded Si areas are rigid, and they conduct electrical current easily. Accordingly, with this technique, a device which passes current through Pt bonded regions which has a high mechanical Q can be designed and manufactured.

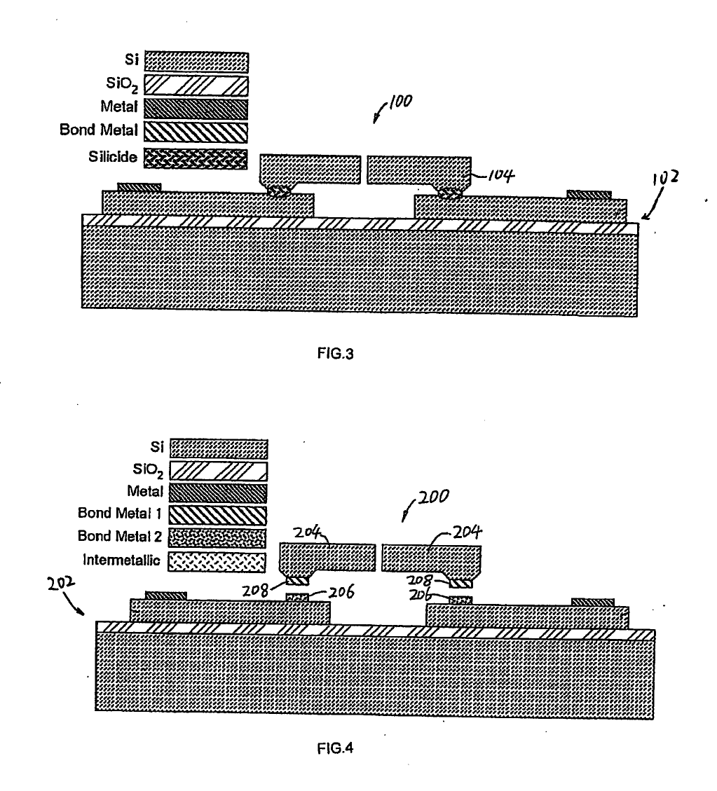

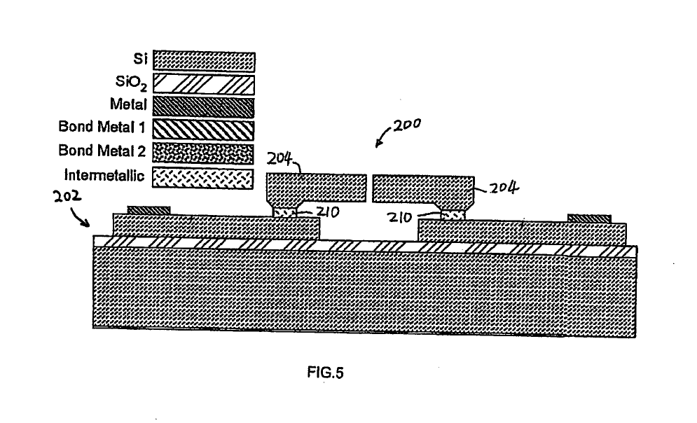

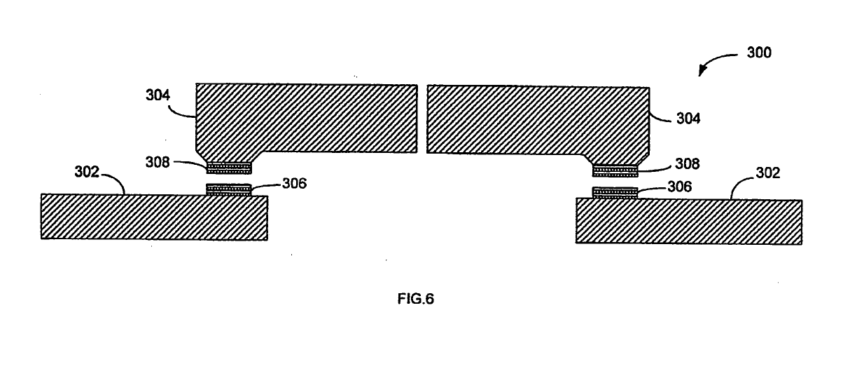

FIGS. 4 and 5 schematically show an alternative method for bonding two substrates together in semiconductor fabrication. In FIGS. 4 and 5, two silicon substrates are used as exemplary substrates, but a person skilled in the art should understand that other substrates, such as substrates made from glass, ceramic, etc., also can be used with the present invention. FIG. 4 shows the MEMS device before the two substrates are bonded together and FIG. 5 shows the MEMS device after the two substrates are bonded together. As seen in the figures, the MEMS device 200 includes a first substrate 202 and a second substrate 204. A first metal is deposited by sputtering, evaporation, or other thin film deposition techniques on bonding areas to form metal contacts 206 on the first substrate 202. A second metal, which is different from the first metal, is deposited by sputtering, evaporation, or other thin film deposition techniques on bonding areas to form metal contacts 208 on the second substrate 204. The metal contacts 206 and 208 preferably have a uniform outer surface. The first and second metals are preferably selected from but not limited to a group consisting of Pt, Pd, Co, Mo, Ta, Cr, Ti, W, Al, Nb, Sn, Zr, Ni, V, and Mo. Alternatively, silicon can be used to replace one of the metals to form a metal silicide bond. The two substrates 202 and 204 are then aligned and the deposited metal contacts 206 and 208 are brought into contact with each other. Preferably, the two substrates 202 and 204 are pressed against each other, such that the deposited metal contacts 206 and 208 are in intimate contact. The two metal contacts 206 and 208 are then annealed at a preferable temperature (preferably below the melting point of the metal contacts) that allows the two metals to diffuse into each other, thereby forming an intermetallic bond 210, as shown in FIG. 5. The intermetallic bond 210 includes intermetallic compounds formed by the atoms of the two metals. An example of such an intermetallic compound which can be used for bonding is Ni₃Al, in which the two metals respectively are Ni and Al. Other metal pairs include but not limited to Pd—Al, Pt—Al, Ti—Al, Ti—Cr, Al—Nb, and Ti—Sn. In one preferred embodiment, the intermetallic bond between the two substrates is characterized by a yield strength of over 50 megapascals. In another preferred embodiment, the intermetallic bond is characterized by a yield strength of over 100 megapascals. According to a further preferred embodiment of the present invention, the intermetallic bond is characterized by a yield strength of over one gigapascal.

FIG. 6 schematically shows another preferred embodiment of the method for bonding two substrates in MEMS applications. FIG. 6 shows the MEMS device 300 including two substrates 302 and 304 to be bonded together. The substrates 302 and 304 have contacts 306 and 308, which are aligned as shown in FIG. 6 and are to be bonded together. Each of the contacts 306 and 308 includes a multi-layer stack of alternating thin layers of at least two materials (preferably two metals), which are deposited on the bonding areas of the substrates 302 and 304 by sputtering, evaporation, or other thin film deposition techniques. For example, each contact may include alternating layers of Ni and Al, or Pd and Al, or Ti and Sn, or Ni and Si, Ti and Al, Ti and Cr, Al and Nb, Pt and Al, or Pt and Si. The arrangement speeds up the inter-diffusion of the bonding materials and intermetallic (or silicide) reactions between the bonding materials. The arrangement may also reduce the temperature required in the annealing process, which allows the bonding materials to diffuse into each other and form an intermetallic bond or a silicide bond.

The process described in this disclosure can be used to manufacture semiconductor devices, for example, MEMS devices which use vibrating proof masses. Exemplary MEMS devices include, but are not limited to, accelerometers, gyroscopes, microphones and cantilevers.

Some examples of intermetallic compounds that can be used to bond two substrates according to the present disclosure are described in the reference: “Intermetallic Compounds: Structural Applications of Intermetallic Compounds”, ed. J. H. Westbrook and R. L. Fleischer, (John Wiley and Sons, 2000, West Sussex, England). Generally, to achieve a lower yield strength, a lower anneal temperature and a shorter anneal time are used, so that only a part of the metals react to form intermetallic compounds. To achieve a higher yield strength, a longer time and a higher temperature are used, such that all the metals react, leaving just silicide or intermetallic compounds.

According to the above cited reference, Ni₃(Al, Ta) has a critical resolved shear stress of about 100-200 MPa, Ni₃(Al, Zr) has a yield strength of about 322 MPa, NiAl has a yield strength of about 200 MPa, TiAl has a yield strength of about 80 MPa, Ti(A144%, Nb10%) has a yield strength of about 770 MPa, Ti(Al48%, Nb10%) has a yield strength of about 400 MPa, Zr₃Al has a yield strength varying between 220-650 MPa depending on the grain size (Note that a reactively formed thin film would have a very small grain size, hence a high yield strength.), Ni₃ (Si, Ti 9%) has a yield strength of about 400 MPa, CoSi₂ has a yield strength of about 500 MPa, and CrSi₂ has a critical resolved shear stress of about 400 MPa and a yield strength of about 500 MPa. See “Intermetallic Compounds: Structural Applications of Intermetallic Compounds”, ed. J. H. Westbrook and R. L. Fleischer, (John Wiley and Sons, 2000, West Sussex, England), chapters 1-3.

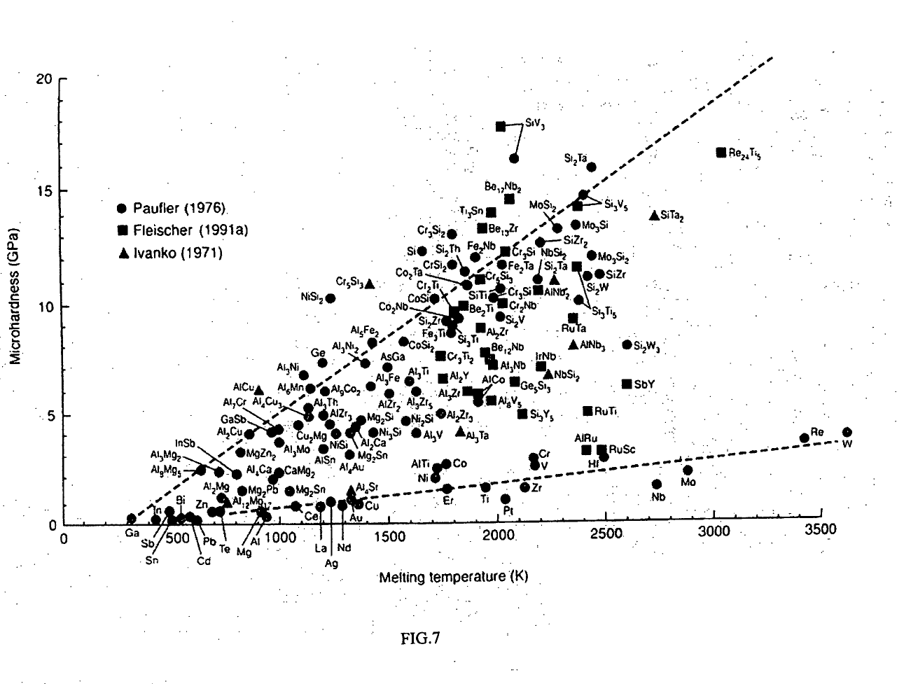

FIG. 7 shows a graph of micro-hardness vs. melting temperature for metals and intermetallic compounds. See “Intermetallic Compounds: Structural Applications of Intermetallic Compounds”, ed. J. H. Westbrook and R. L. Fleischer, (John Wiley and Sons, 2000, West Sussex, England), page 257. Yield strength is typically about ⅓ of micro-hardness. As seen in FIG. 7, the intermetallic compounds including Ni—Al, Ti—Al, Ti—Cr, Al—Nb, Ti—Sn, etc. and silicide including Ni—Si etc. have micro-hardness greater than 3 GPa, which translates to a room temperature yield strength greater than 1 GPa.

The yield strength required for zero creep depends on the stress applied to the MEMS device during use and storage. The stress applied to the MEMS device during use and storage typically is less than 200 MPa, and should be even lower for a high reliability device. Therefore, for the structure constructed according to the present invention, there is almost no possibility of creep, and thereby drift free operation is assured.

While the claimed invention has been described in detail and with reference to specific embodiments thereof, it will be apparent to one of ordinary skill in the art that various changes and modifications can be made to the claimed invention without departing from the spirit and scope thereof. Thus, for example those skilled in the art will recognize, or be able to ascertain, using no more than routine experimentation, numerous equivalents to the specific substances and procedures described herein. Such equivalents are considered to be within the scope of this invention, and are covered by the following claims.

What is claimed is:

1. A method of bonding substrates comprising:
depositing a first metal in a bonding area on a first substrate;
depositing a second metal in a bonding area on a second substrate, wherein said second metal differs from said first metal;
patterning said metals;
placing said first substrate and said second substrate together, wherein said deposited first metal on said first substrate is aligned and in contact with said deposited second metal on said second substrate; and
annealing said first metal and said second metal to form an intermetallic bond between said first substrate and said second substrate.

2. A method according to claim 1, wherein said first metal and said second metal are selected from a group consisting of Pt, Pd, Co, Mo, Ta, Cr, Ti, W, Al, Nb, Sn, Zr, Ni, V, and Mo.

3. A method according to claim 1, wherein said first metal and said second metal are selected from a group of metal pairs consisting of Ni—Al, Ti—Al, Ti—Cr, Al—Nb, Pd—Al, Pt—Al and Ti—Sn.

4. A method according to claim 1, wherein said intermetallic bond forms an ohmic contact between said first substrate and said second substrate.

5. A method according to claim 1, wherein said intermetallic bond is characterized by a yield strength of over 50 megapascals.

6. A method according to claim 1, wherein said intermetallic bond is characterized by a yield strength of over 100 megapascals.

7. A method according to claim 1, wherein said intermetallic bond is characterized by a yield strength of over one gigapascal.

8. A method of bonding a first substrate to a silicon substrate comprising:
depositing a metal in a bonding area on said first substrate;
patterning said metal;
placing said first substrate and said silicon substrate together, wherein said deposited metal is between said first substrate and said silicon substrate; and
annealing said two substrates such that said metal diffuses into said silicon substrate and silicon diffuses into said metal to form metal silicide, thereby to form a bond between said first substrate and said silicon substrate.

9. A method according to claim 8, wherein said metal is selected from a group consisting of Pt, Pd, Co, Mo, Ta, Cr, Ti, W, Al, Nb, Sn, Zr, Ni, V, and Mo.

10. A method according to claim 8, wherein said bond forms an ohmic contact between said first substrate and said silicon substrate.

11. A method according to claim 8, wherein said bond is characterized by a yield strength of over 50 megapascals.

12. A method according to claim 8, wherein said bond is characterized by a yield strength of over 100 megapascals.

13. A method according to claim 8, wherein said bond is characterized by a yield strength of over one gigapascal.

14. A method according to claim 8, wherein said annealing step is performed at a temperature of about 335° C.

15. A method of bonding substrates comprising:
depositing a first bonding material layer in a bonding area on a first substrate, wherein said first bonding material layer includes alternating layers of at least two materials;
depositing a second bonding material layer in a bonding area on a second substrate, wherein said second bonding material layer includes alternating layers of said at least two materials;
patterning said bonding materials;
placing said first substrate and said second substrate together, wherein said deposited first bonding material layer on said first substrate is aligned and in contact with said deposited second bonding material layer on said second substrate; and
annealing said first and second bonding material layers to form a bond between said first substrate and said second substrate.

16. A method according to claim 15, wherein said at least two materials are selected from a group consisting of Pt, Pd, Co, Mo, Ta, Cr, Ti, W, Al, Nb, Sn, Zr, Ni, V, Mo, and Si.

17. A method according to claim 15, wherein said at least two materials are selected from a group of material pairs consisting of Ni—Al, Ti—Al, Ti—Cr, Al—Nb, Ti—Sn, Pd—Al, Pt—Al, Pt—Si, and Ni—Si.

18. A method according to claim 15, wherein said bond forms an ohmic contact between said first substrate and said second substrate.

19. A method according to claim 15, wherein said bond is characterized by a yield strength of over 50 megapascals.

20. A method according to claim 15, wherein said bond is characterized by a yield strength of over 100 megapascals.

21. A method according to claim 15, wherein said bond is characterized by a yield strength of over one gigapascal.

22. A MEMS device comprising:
a first substrate and a second substrate bonded by an intermetallic bond between said first substrate and said second substrate, said intermetallic bond comprising intermetallic compounds containing at least two metals.

23. A MEMS device according to claim 22, wherein said first substrate and said second substrate are made from materials selected from a group consisting of silicon, silicon carbide, glass, ceramic, fused silicon dioxide, and PYREX™.

24. A MEMS device according to claim 22, wherein said at least two metals are selected from a group consisting of Pt, Pd, Co, Mo, Ta, Cr, Ti, W, Al, Nb, Sn, Zr, Ni, V, and Mo.

25. A MEMS device according to claim 22, wherein said intermetallic bond between said first substrate and said second substrate is electrically conductive.

26. A MEMS device according to claim 22, wherein said intermetallic bond is characterized by a yield strength of over 50 megapascals.

27. A MEMS device according to claim 22, wherein said intermetallic bond is characterized by a yield strength of over 100 megapascals.

28. A MEMS device according to claim 22, wherein said intermetallic bond is characterized by a yield strength of over one gigapascal.

29. A MEMS device according to claim 22, wherein said at least two metals are selected from a group of metal pairs consisting of Ni—Al, Ti—Al, Ti—Cr, Al—Nb, Pd—Al, Pt—Al and Ti—Sn.

30. A MEMS device comprising:
a first substrate and a second substrate, wherein at least one of said two substrates is made from silicon,
wherein said first substrate and said second substrate are bonded by a metal silicide bond between said first and second substrates.

31. A MEMS device according to claim 30, wherein the other substrate is made from a material selected from a group consisting of silicon, silicon carbide, glass, ceramic, fused silicon dioxide, and PYREX™.

32. A MEMS device according to claim 30, wherein said metal of said metal silicide bond is selected from a group consisting of Pt, Pd, Co, Mo, Ta, Cr, Ti, W, Al, Nb, Sn, Zr, Ni, V, and Mo.

33. A MEMS device according to claim 30, wherein said metal silicide bond between said first and second substrates is electrically conductive.

34. A MEMS device according to claim 30, wherein said bond between said first and second substrates is characterized by a yield strength of over 50 megapascals.

35. A MEMS device according to claim 30, wherein said bond between said first and second substrates is characterized by a yield strength of over 100 megapascals.

36. A MEMS device according to claim 30, wherein said bond between said first and second substrates is characterized by a yield strength of over one gigapascal.

37. A MEMS device comprising:
a first substrate;
a second substrate;
wherein said first substrate and said second substrate are bonded with a bond formed by a process comprising:
depositing a first bonding material layer in a bonding area on said first substrate, wherein said first bonding material layer includes alternating layers of at least two materials;
depositing a second bonding material layer in a bonding area on said second substrate, wherein said second bonding material layer includes alternating layers of said at least two materials;
patterning said bonding materials;
placing said first substrate and said second substrate together, wherein said deposited first bonding material layer on said first substrate is aligned and in contact with said deposited second bonding material layer on said second substrate; and
annealing said first and second bonding material layers to form said bond between said first substrate and said second substrate.

38. A method according to claim 37, wherein said at least two materials are selected from a group consisting of Pt, Pd, Co, Mo, Ta, Cr, Ti, W, Al, Nb, Sn, Zr, Ni, V, Mo, and Si.

39. A method according to claim 37, wherein said bond forms an ohmic contact between said first substrate and said second substrate.

40. A method according to claim 37, wherein said bond is characterized by a yield strength of over 50 megapascals.

41. A method according to claim 37, wherein said intermetallic bond is characterized by a yield strength of over 100 megapascals.

42. A method according to claim 37, wherein said bond is characterized by a yield strength of over one gigapascal.

43. A MEMS device according to claim 37, wherein said first substrate and said second substrate are made from materials selected from a group consisting of silicon, silicon carbide, glass, ceramic, fused silicon dioxide, and PYREX™.

44. A method according to claim 37, wherein said at least two materials are selected from a group of material pairs consisting of Ni—Al, Ti—Al, Ti—Cr, Al—Nb, Ti—Sn, Pd—Al, Pt—Al, Pt—Si, and Ni—Si.

45. A method of bonding substrates comprising:
depositing a metal in a bonding area on a first substrate, wherein said metal is selected from a group consisting of Pt, Pd, Co, Mo, Ta, Cr, Ti, W, Al, Nb, Sn, Zr, Ni, V, and Mo;
depositing silicon in a bonding area on a second substrate;
patterning said deposited metal and said deposited silicon;
placing said first substrate and said second substrate together, wherein said deposited metal on said first substrate is aligned and in contact with said deposited silicon on said second substrate; and
annealing said metal and said silicon to form a metal silicide bond between said first substrate and said second substrate.
